(19) United States
(12) Patent Application Publication
(10) Pub. No.: US 2002/0096763 A1
(43) Pub. Date: Jul. 25, 2002

(54) Packaging structure of image sensors and method for packaging the same

(76) Inventors: Mon Nan Ho, Hsinchu Hsien (TW); Hsiu Wen Tu, Hsinchu Hsien (TW); C. S. Cheng, Hsinchu Hsien (TW); Li Huan Chen, Hsinchu Hsien (TW); Joe Liu, Hsinchu Hsien (TW); Jichen Wu, Hsinchu Hsien (TW); Wen Chuan Chen, Hsinchu Hsien (TW)

Correspondence Address: Keith Kline, PRO-TECHTOR INTERNATIONAL SERVICES, 20775 Norada Court, Saratoga, CA, 95070-3018, US

(21) Appl. No.: 09/768,986

(22) Filed: Jan. 23, 2001

(51) Int. Cl. H01L 23/06

(52) U.S. Cl. 257/729

(57) ABSTRACT

A packaging structure of an image sensor includes a plurality of metal sheets, an image sensing chip, and transparent glue. Each of the metal sheets has a first surface and a second surface. The image sensing chip is electrically connecting to the plurality of first surfaces of the metal sheets. The transparent glue is for covering the metal sheets and the image sensing chip is capable of receiving optical signals. The second surfaces of the metal sheets bonded by the transparent glue are exposed to the outside so as to form signal output terminals for the image sensor. A method for packaging the structure is also disclosed.

### BACKGROUND OF THE INVENTION

1. Field of the Invention

The invention relates to a packaging structure of image sensors and method for packaging the same, in particular, to a transparent layer of an image sensor formed by transparent glue which can be integrally formed with the substrate in packaging, thereby lowering the manufacturing costs.

2. Description of the Related Art

In typical image sensors, in order to achieve the demands for high heat dissipating efficiency and high sealing property, the substrate for carrying the image sensing chip is formed from ceramic materials. A plurality of [symbol] -shaped pins connected to each another are formed on the periphery of the substrate. The image sensing chip is placed on the substrate. Then, the image sensing chip is electrically connected to the pins on the top surface of the substrate by a plurality of wirings. Next, a transparent glass is used to cover the image sensing chip to complete the package of the image sensor. Thus, the pins on the bottom surface of the substrate can be electrically connected to the circuit board in the image sensor after packaging.

In the substrate of the image sensor including ceramic materials, it should be noted that both the selection of the components of the ceramic materials and the control of the working temperature are very important in manufacturing processes. If an improper selection or control is made, the substrate may be easily deformed or cracked. Furthermore, since the ceramic substrate cannot be easily cut without any crack, it must be made individually. Therefore, a lot of ceramic substrates cannot be manufactured at the same time, causing the manufacturing costs relatively high.

Moreover, since the pins on the bottom surface of the substrate are used for electrically connecting to the circuit board, the pins have to form a flat contact surface in order not to influence the electrical connection relationship between the substrate and the circuit board. However, the prior art pins are formed into “ [symbol] ” shapes on the top and bottom surfaces by pressing. As a result, it is not easy to form a plurality of flat pins, thereby influencing the signal transmission in the image sensor.

In addition, the signal transmission distances for the [symbol] -shaped pins are relatively long. Therefore, the signal transmission between the image sensing chip and the substrate is also influenced.

Furthermore, when packaging the photosensitive image sensing chip, a transparent glass has to cover the image sensing chip so that the optical signal from the image sensing chip can be output via the transparent glass. Therefore, the manufacturing processes are not convenient.

In order to solve the above problems, it is necessary to provide a packaging structure and method for an image sensor in which the manufacturing costs can be lowered and the signal transmission of the image sensing chip can be improved.

### SUMMARY OF THE INVENTION

It is therefore an object of the invention to provide a packaging structure and method for an image sensor which can be manufactured in large quantities to lower the manufacturing costs.

Another object of the invention is to provide a packaging structure and method for an image sensor in which the signal transmission distances can be made shorter to perform better signal transmission properties.

According to one aspect of the invention, a packaging structure of an image sensor includes a plurality of metal sheets, an image sensing chip, and transparent glue. Each of the metal sheets has a first surface and a second surface. The image sensing chip is electrically connected to the plurality of first surfaces of the metal sheets. The transparent glue is for covering the metal sheets and the image sensing chip is capable of receiving optical signals. The second surfaces of the metal sheets bonded by the transparent glue are exposed to the outside so as to form signal output terminals for the image sensor.

According to the above-mentioned structure, the second surfaces of the metal sheets can smoothly connect to the circuit board, and the signal transmission distances between the image sensing chip and the circuit board can be shortened so as to obtain better signal transmission properties. Furthermore, by using the transparent glue to seal the metal sheets and image sensing chip, a lot of image sensors can be manufactured at the same time by way of molding. Moreover, since the transparent glue allows light to pass through it, the image sensing chip can be protected and can receive optical signals. Therefore, the process of covering a piece of glass can be omitted, and the manufacturing costs can be lowered.

### BRIEF DESCRIPTION OF THE DRAWINGS

FIG. 1 is a cross-sectional view showing the packaging structure of the image sensor according to the invention.

FIG. 2 is a first schematic illustration showing the packaging method of the image sensor according to the invention.

FIG. 3 is a second schematic illustration showing the packaging method of the image sensor according to the invention.

FIG. 4 is a third schematic illustration showing the packaging method of the image sensor according to the invention.

### DETAIL DESCRIPTION OF THE INVENTION

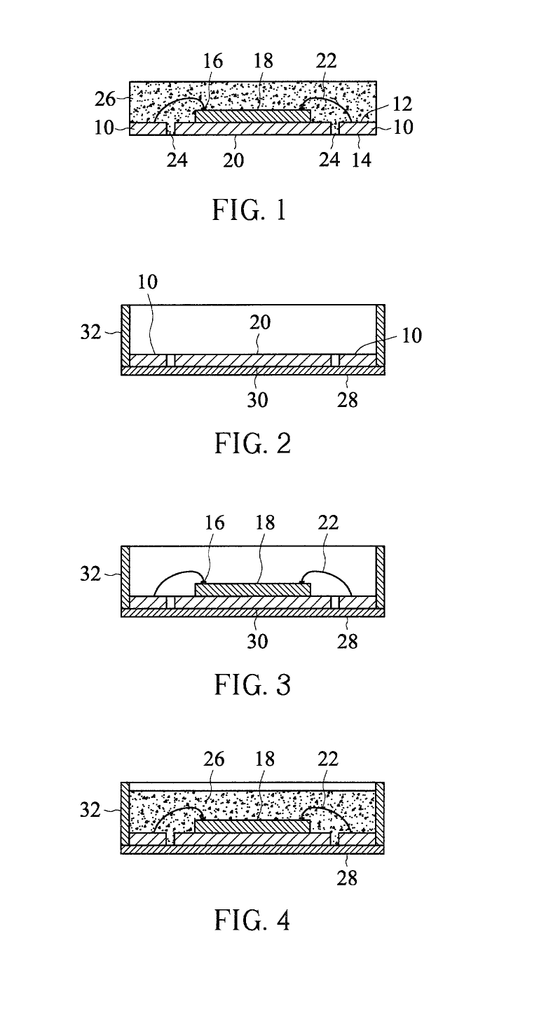

Referring to FIG. 1, the packaging structure of the image sensor of the invention includes a plurality of metal sheets 10. Each of the metal sheets 10 includes a first surface 12 serving as a signal input terminal, and a second surface 14 serving as a signal output terminal. An image sensing chip 18 formed with a plurality of bonding pads 16 is placed on a carrier 20. A plurality of wirings 22 are formed to electrically connect the image sensing chip 18 to each of the metal sheets 10. The first surfaces 12 of the metal sheets 10 are electrically connected to the bonding pads 16 of the image sensing chip 18 through the wirings 22 by way of wiring bonding. Thus, the signal from the image sensing chip 18 can be transmitted to the first surfaces 12 of the metal sheets 10, and then transmitted to the circuit board (not shown) via the second surfaces 14. The carrier 20 is made of metallic material, and is integrally formed with the metal sheets 10 by pressing. A gap 24 is formed between two adjacent metal sheets 10 and between each of the metal sheets 10 and the carrier 20. Thus, each of the metal sheets 10 is isolated from one another. The image sensing chip 18 is placed on the carrier 20.

Transparent glue 26 is used for covering each of the metal sheets 10 and the image sensing chip 18. Furthermore, the gaps 24 are filled with transparent glue 26 so that each of the metal sheets 10 is firmly adhered to the carrier 20. The second surfaces 14 of the metal sheets 10 bonded by the transparent glue 26 are exposed to the outside so as to form the signal output terminals for the image sensor. Consequently, the image sensing chip 18 covered by the transparent glue 26 is capable of receiving optical signals and transmitting the signals to the outside through the second surfaces 14 of the metal sheets 10.

Referring to FIG. 2, the packaging method of the image sensor of the invention is described hereinbelow. First, adhere a plurality of metal sheets 10 and a carrier 20 to a tape 28. The tape 28 is provided with a holding region 30 for holding the image sensing chip 18 therein. The holding region 30 is a region for placing the carrier 20. Then, place the tape 28 within a hollow mold 32.

Referring to FIG. 3, the packaging method is further described hereinbelow. Second, place the image sensing chip 18 having a plurality of bonding pads 16 on the carrier 20 located within the holding region 30 of the tape 28. Next, connect the bonding pads 16 of the image sensing chip 18 to the metal sheets 10 via a plurality of wirings 22 by way of wiring bonding. Therefore, the signals form the image sensing chip 18 can be transmitted to the first surfaces 12 of the metal sheets 10 and transmitted to a circuit board (not shown) through the second surfaces 14 of the metal sheets 10.

Referring to FIG. 4, the packaging method is still further described hereinbelow. Third, after the wiring bonding process is complete to electrically connect the image sensing chip 18 to the metal sheets 10, pour the transparent glue 26 into the mold 32 in order to pack the metal sheets 10, wirings 22, and image sensing chip 18. Since the light can be transmitted to the image sensing chip 18 through transparent glue 26, the image sensing chip 18 can receive optical signals and transmit the signals to the metal sheets 10. Finally, tear the tape 28 and take the image sensor off the mold 32 in order to complete the packaging processes.

The packaging structure and method of the invention have the following advantages.

1. Since the signals from the image sensing chip 18 can be transmitted to the circuit board by the thin metal sheets 10, relatively short transmission distances and better signal transmission effects can be obtained.

2. Since the metal sheets 10 have smooth second surfaces 14, better electric contacting effects between the metal sheets 10 and the circuit board can be obtained.

3. A large amount of substrates can be formed at the same time by molding. Then, the substrates can be cut into a plurality of single substrates. As a result, the substrates can be quickly made so that the manufacturing costs can be lowered.

4. Since the plastic material for forming the package structure is cheaper than the ceramic material used in the prior art, the package costs also can be lowered.

5. By using the transparent glue 26 instead of a transparent glass, the process of covering the transparent glass can be omitted. Furthermore, the substrate can be formed simultaneously with the process of pouring the transparent glue 26, thereby lowering the manufacturing costs.

While the invention has been described by way of example and in terms of preferred embodiments, it is to be understood that the invention is not limited to the disclosed embodiments. To the contrary, it is intended to cover various modifications. Therefore, the scope of the appended claims should be accorded the broadest interpretation so as to encompass all such modifications.

What is claimed is:

1. A packaging structure of an image sensor, comprising:
a plurality of metal sheets each of which having a first surface and a second surface;
an image sensing chip electrically connected to the plurality of first surfaces of the metal sheets; and
transparent glue for covering the metal sheets and the image sensing chip, wherein the image sensing chip is capable of receiving optical signals, and the second surfaces of the metal sheets bonded by the transparent glue are exposed to the outside so as to form signal output terminals for the image sensor.

2. The packaging structure of the image sensor according to claim 1, wherein the metal sheets are smooth metal sheets.

3. The packaging structure of the image sensor according to claim 1, wherein the image sensing chip is electrically connected to the first surfaces of the metal sheets through a plurality of wirings by way of wiring bonding.

4. The packaging structure of the image sensor according to claim 1, wherein the image sensing chip is mounted on a carrier and covered by transparent glue.

5. The packaging structure of the image sensor according to claim 4, wherein the image sensing chip is integrally formed with the carrier.

6. A method for packaging an image sensor, comprising the steps of:
adhering a plurality of metal sheets onto a tape, the tape including a holding region for holding the image sensing chip therein;
placing the tape into a hollow mold;
placing an image sensing chip having a plurality of bonding pads onto the holding region of the image sensing chip;
electrically connecting the bonding pads of the image sensing chip to the metal sheets using a plurality of wirings;
pouring transparent glue into the mold to seal the metal sheets, the image sensing chip, and the plurality of wirings so as to form a packaging structure; and
taking out the image sensor from the mold and tearing off the tape with the metal sheets exposed to the outside through the transparent glue.

7. The method for packaging the image sensor according to claim 6, wherein the image sensing chip is electrically connected to the first surfaces of the metal sheets through a plurality of wirings by way of wiring bonding.

8. The method for packaging the image sensor according to claim 6, wherein a carrier is placed on the holding region of the tape, and the image sensing chip is placed on the carrier.

9. The method for packaging the image sensor according to claim 8, wherein the plurality of metal sheets are integrally formed with the carrier.
